(19) United States
(12) Patent Application Publication
(10) Pub. No.: US 2005/0067950 A1
(43) Pub. Date: Mar. 31, 2005

(54) Organic electroluminescent device

(76) Inventors: Hiroshi Nonoue, Osaka (JP); Hiroaki Izumi, Osaka (JP); Katsutoshi Takeda, Osaka (JP); Masahiro Iyori, Osaka (JP)

Correspondence Address: MCDERMOTT, WILL & EMERY, 600 13th Street, N.W., Washington, DC, 20005-3096, US

(21) Appl. No.: 10/809,827

(22) Filed: Mar. 26, 2004

(30) Foreign Application Priority Data
Mar. 27, 2003 (JP) 2003-089414
Mar. 22, 2004 (JP) 2004-083665

(51) Int. Cl. H05B 33/14; H05B 33/00

(52) U.S. Cl. 313/504; 313/503; 313/506

(57) ABSTRACT

An organic EL device comprises a transparent substrate, a hole injection electrode, an electron-donating organic compound layer, a light emitting layer, an electron-accepting organic compound layer, an electron injection electrode and a filter. The filter is integrally formed on the lower surface of the transparent substrate. The filter blocks transmission of light in a prescribed wavelength range. The prescribed wavelength range is a range up to a wavelength longer by 50 nm with reference to the wavelength of light generating the maximum electromotive force in optical power generation of the organic EL device.

### BACKGROUND OF THE INVENTION

1. Field of the Invention

The present invention relates to an organic electroluminescent device.

2. Description of the Background Art

In recent years, with increasing diversity in information equipment, there is a growing need for flat panel display devices that require smaller power consumption than CRTs (Cathode Ray Tube) generally in use. As one of the flat penal display devices, an organic electroluminescent (hereinafter abbreviated as organic EL) device characterized by having high efficiency, small thickness, light weight, and low angular-field-of-view dependency is drawing attention.

An organic EL device is a self-light emitting device injection electrons and holes into a light emitting layer of an organic material from an electron injection electrode and a hole injection electrode respectively and recombining the injected electrons and holes with each other at the light emitting center thereby exciting organic molecules, for generating fluorescence when the organic molecules return from the excited state to a ground state.

This organic EL device is deteriorated due to incidence of light into the device, employment over a long period use or heating. More specifically, the deterioration of the organic molecules results in reduction of the luminance of the organic EL device, or an increase of a drive voltage for attaining constant luminance (this deterioration is hereinafter referred to as voltage increase deterioration), for example.

In general, the cause for deterioration of an organic EL device resulting from incidence of light into the device has been regarded as photo decomposition of organic molecules caused by ultraviolet light (light having wavelengths of about 1 to 400 nm). Further, the main factor for such photo decomposition of the organic molecules caused by ultraviolet light has been regarded as the presence of residual oxygen and moisture in the device or the like.

In order to prevent this deterioration of the organic EL device, a method of sealing the organic EL device itself in an inert gas atmosphere or a method of preventing the organic EL device from entrance of ultraviolet light by providing a layer blocking ultraviolet light has been proposed (refer to JP-4-334895-A or JP-2002-184572-A).

However, the voltage increase deterioration is caused when not only ultraviolet light but also visible light enters the device.

### SUMMARY OF THE INVENTION

An object of the present invention is to provide an organic electroluminescent device capable of sufficiently reducing an increase of a drive voltage caused by entrance of light.

An organic electroluminescent device has an optical power generation property of generating electromotive force upon incidence of light having a specific wavelength. Therefore, the inventors have noticed the mechanism of an increase of a drive voltage for the organic electroluminescent device caused upon entrance of not only ultraviolet light but also visible light, and made the following researches:

First, the inventors have researched the relation between optical power generation of organic electroluminescent devices and the wavelengths of incident light into the same.

This research was made on three types of organic electroluminescent devices S1, S2 and S3 each having a basic structure obtained by successively stacking a hole injection electrode, an electron-donating organic compound layer, an electron-accepting organic compound layer and an electron injection electrode on a glass substrate. These three types of organic electroluminescent devices S1, S2 and S3 have different properties depending upon additives or further layers added to the aforementioned basic structure.

In each of the organic electroluminescent devices S1 to S3, tris(8-hydroxyquinolinato)-aluminum (hereinafter abbreviated as Alq) was employed as the material for the electron-accepting organic compound layer, and N,N′-di(naphthalene-1-yl)-N,N′-diphenyl-benzidine (hereinafter abbreviated as NPB) was employed as the material for the electron-donating organic compound layer.

Alq has a molecular structure expressed in the following chemical formula (1):

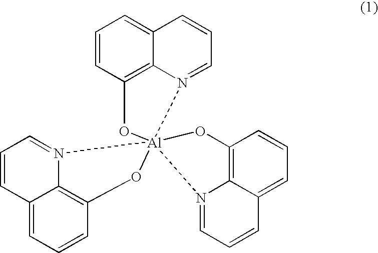

NPB has a molecular structure expressed in the following chemical formula (2):

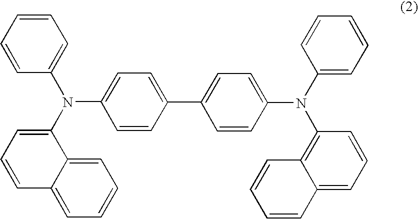

Light having a plurality of different wavelengths were introduced into each of the organic electroluminescent devices SI to S3 through a spectrometer, for measuring generated electromotive force every wavelength.

FIG. 1 is a graph showing the relation between electromotive force in optical power generation of the organic electroluminescent devices S1 to S3 and the wavelengths of the incident light. Referring to FIG. 1, the axis of ordinate shows power generation strength (electromotive force generated by the organic electroluminescent devices S1 to S3), and the axis of abscissa shows the wavelengths of the incident light into the organic electroluminescent devices S1 to S3.

The solid line K1, the broken line K2 and the one-dot chain line K3 show the levels of power generation strength of the organic electroluminescent devices S1, S2 and S3 respectively.

According to FIG. 1, the organic electroluminescent device S1 generated the maximum electromotive force with the incident light having the wavelength of about 400 nm. Further, this device S1 generated electromotive force of at least about 50% of the maximum electromotive force with the incident light in the wavelength range of about 300 nm to about 450 nm.

The organic electroluminescent device S2 generated the maximum electromotive force with the incident light having the wavelength of about 390 nm. Further, this device S2 generated electromotive force of at least about 50% of the maximum electromotive force with the incident light in the wavelength range of about 300 nm to about 420 nm.

The organic electroluminescent device S3 generated the maximum electromotive force with the incident light having the wavelength of about 420 nm. Further, this device S3 generated electromotive force of at least about 50% of the maximum electromotive force with the incident light in the wavelength range of about 360 nm to about 470 nm.

Thus, it has been clarified that optical power generation of an organic electroluminescent device has optical wavelength dependency. It has also been clarified that an organic electroluminescent device having the aforementioned basic structure generates the maximum electromotive force with incident light having a wavelength of about 390 nm to about 420 nm, and generates electromotive force of at least about 50% of the maximum electromotive force with incident light in the wavelength range of not more than about 300 nm up to about 470 nm. It has further been clarified that the organic electroluminescent device generates electromotive force with incident light having a wavelength of about 500 nm at the maximum on the long-wavelength side.

Then, the inventors have researched whether or not there is a cause-and-effect relationship between optical power generation of organic electroluminescent devices and optical absorption characteristics of organic materials employed for the organic electroluminescent devices.

FIG. 2 is a graph showing the relation between optical absorption wavelengths and absorption intensity of Alq and NPB. Referring to FIG. 2, the axis of ordinate shows the optical absorption intensity, and the axis of abscissa shows the optical absorption wavelengths. The solid line KA and the broken line KN show the optical absorption spectra of Alq and NPB respectively.

According to FIG. 2, Alq, exhibiting the maximum absorption intensity at the optical absorption wavelength of about 380 nm, absorbs light in the wavelength range of not more than about 300 nm up to about 440 nm. On the other hand, NPB, exhibiting the maximum absorption intensity at the optical absorption wavelength of about 340 nm, absorbs light in the wavelength range of not more than about 300 nm up to about 410 nm. It is inferred from these results that Alq is most activated with light having the wavelength of about 380 nm while NPB is most activated with light having the wavelength of about 340 nm.

If there is a cause-and-effect relationship between optical power generation of an organic electroluminescent device and optical absorption characteristics of an organic material therefore, the organic electroluminescent device conceivably exhibits the maximum electromotive force in optical power generation with incident light having the wavelength of about 380 nm or about 340 nm. However, the organic electroluminescent device obtains the maximum electromotive force with incident light in the wavelength range of about 390 nm to about 420 nm.

While an organic electroluminescent device causes optical power generation in the wavelength range of not more than 300 nm up to about 500 nm, neither Alq nor NPB can absorb light having the wavelength of about 500 nm. Therefore, the inventors have considered that there is no cause-and-effect relationship between optical power generation of an organic electroluminescent device and optical absorption characteristics of an organic material therefore.

On the other hand, the inventors have prepared an organic electroluminescent device capable of blocking transmission of light having a specific wavelength and made a research as to an increase of a drive voltage in undermentioned example. The wording “blocking transmission of light” is not restricted to a case of blocking transmission of light by 100% (transmittance: 0%) but also includes a case of blocking transmission of partial light while allowing transmission of the remaining light (transmittance: greater than 0% and less than 100%).

Thus, the inventors have obtained such a result that an increase of the drive voltage causing deterioration of the organic electroluminescent device can be reduced by preventing the light having a wavelength causing optical power generation from entering the device.

Consequently, the inventors have found out such a possibility that an increase of the drive voltage results from optical power generation of the organic electroluminescent device.

In optical power generation, carriers are generated in the organic electroluminescent device. The generated carriers disappear on the interface between a light emitting layer consisting an organic material and an electron injection electrode or a hole injection electrode. Thus, partial Joule heat is generated in disappearance of the carriers to alter a portion around the interface, to conceivably result in an increase of the drive voltage.

Thus, an increase of resistance in current injection is conceivable as the principal factor for the mechanism of an increase of the drive voltage. In other words, an increase of the drive voltage conceivably results from alteration of the interface between the electrode and the light emitting layer and in the vicinity thereof.

Therefore, the inventors have considered that an increase of the drive voltage can be sufficiently reduced by preventing the light having the wavelength causing optical power generation from entering the organic electroluminescent device, also when not only ultraviolet light in the range UV shown in FIG. 1 but also visible light in the range V enters the device.

An organic electroluminescent device according to a first aspect of the present invention comprises a light emitting layer composed of an organic compound and a light blocking layer blocking incidence of light in a prescribed wavelength range in the light emitting layer, while the light emitting layer generates a voltage having a peak at a specific wavelength by external photoirradiation, and the prescribed wavelength range includes the specific wavelength.

In this organic electroluminescent device, the light emitting layer generates the voltage having a peak at the specific wavelength by external photoirradiation. In this case, the light blocking layer prevents the light in the prescribed wavelength range including the specific wavelength from entering the light emitting layer. Thus, the light emitting layer is prevented from generation of a voltage resulting from entrance of the light in the prescribed wavelength range. Consequently, an increase of a drive voltage for the organic electroluminescent device for attaining constant luminance is sufficiently reduced.

The prescribed wavelength range may include a range from the specific wavelength to a wavelength longer by 50 nm than the specific wavelength.

In this case, the light blocking layer prevents the light in the range from the specific wavelength to the wavelength longer by 50 nm than the specific wavelength from entering the light emitting layer. Thus, the light emitting layer is prevented from generation of a voltage resulting from entrance of light in the range from the specific wavelength to the wavelength longer by 50 nm than the specific wavelength. Consequently, an increase of the drive voltage for the organic electroluminescent device for attaining constant luminance is sufficiently reduced.

The prescribed wavelength range may further include a range from the specific wavelength to a wavelength shorter by 50 nm than the specific wavelength.

In this case, the light blocking layer prevents the light in the range from the specific wavelength to the wavelength shorter by 50 nm than the specific wavelength from entering the light emitting layer. Thus, the light emitting layer is prevented from generation of a voltage resulting from entrance of light in the range from the specific wavelength to the wavelength shorter by 50 nm than the specific wavelength. Consequently, an increase of the drive voltage for the organic electroluminescent device for attaining constant luminance is sufficiently reduced.

The prescribed wavelength range may further include a range from the specific wavelength to a wavelength longer by 100 nm than the specific wavelength.

In this case, the light blocking layer prevents the light in the range from the specific wavelength to the wavelength longer by 100 nm than the specific wavelength from entering the light emitting layer. Thus, the light emitting layer is prevented from generation of a voltage resulting from entrance of light in the range from the specific wavelength to the wavelength longer by 100 nm than the specific wavelength. Consequently, an increase of the drive voltage for the organic electroluminescent device for attaining constant luminance is sufficiently reduced.

The prescribed wavelength range may further include a range from the specific wavelength to a wavelength shorter by 100 nm than the specific wavelength.

In this case, the light blocking layer prevents the light in the range from the specific wavelength to the wavelength shorter by 100 nm than the specific wavelength from entering the light emitting layer. Thus, the light emitting layer is prevented from generation of a voltage resulting from entrance of light in the range from the specific wavelength to the wavelength shorter by 100 nm than the specific wavelength. Consequently, an increase of the drive voltage for the organic electroluminescent device for attaining constant luminance is sufficiently reduced.

Transmittance in the light blocking layer at the specific wavelength is preferably lower than the maximum transmittance on the long-wavelength length side beyond the prescribed wavelength range. Thus, light emitted in the light emitting layer is effectively taken out.

The maximum transmittance in the light blocking layer in the prescribed wavelength range is preferably lower than the maximum transmittance on the long-wavelength length side beyond the prescribed wavelength range. Thus, the light emitted in the light emitting layer is further effectively taken out.

Transmittance in the light blocking layer at the specific wavelength may be not more than 80%. Thus, the light blocking layer blocks at least 20% of light at the specific wavelength.

The maximum transmittance in the light blocking layer in the prescribed wavelength range may be not more than 80%. Thus, the light blocking layer blocks at least 20% of light in the prescribed wavelength range.

The organic electroluminescent device may further comprise a light-transmitting electrode provided on one side of the light emitting layer, and the light blocking layer may be arranged on the one side of the light emitting layer. In this case, light generated by the light emitting layer is transmitted through the light-transmitting electrode and taken out from the optical electroluminescent device, while the light blocking layer prevents external light in the prescribed wavelength range from entering the light emitting layer.

The light blocking layer may include an optical filer arranged on the one side of the light emitting layer. In this case, light generated by the light emitting layer is transmitted through the optical filter and taken out from the optical electroluminescent device, while the optical filter prevents external light in the prescribed wavelength range from entering the light emitting layer.

The light blocking layer may include a thin film arranged on the one side of the light emitting layer. In this case, light generated by the light emitting layer is transmitted through the thin film and taken out from the optical electroluminescent device, while the thin film prevents external light in the prescribed wavelength range from entering the light emitting layer. Thus, no specific member or mechanism may be added in order to block the light in the prescribed wavelength range, whereby the structure of the organic electroluminescent device itself is simplified for implementing a thin-film device.

The light-transmitting electrode may include the light blocking layer. In this case, light generated by the light emitting layer is transmitted through the light-transmitting electrode and taken out from the organic electroluminescent device, while the light-transmitting electrode prevents external light in the prescribed wavelength range from entering the light emitting layer. Thus, no specific member or mechanism may be added in order to block the light in the prescribed wavelength range, whereby the structure of the organic electroluminescent device itself is simplified for implementing a thin-film device. Further, the light-transmitting electrode including the light blocking layer is also effectively applicable to a top emission structure.

The organic electroluminescent device may further comprise an organic compound layer provided between the light emitting layer and the light-transmitting electrode, and the organic compound layer may include the light blocking layer. In this case, light generated by the light emitting layer is transmitted through the organic compound layer and the light-transmitting electrode and taken out from the organic electroluminescent device, while the organic compound layer prevents external light in the prescribed wavelength range from entering the light emitting layer. Thus, no specific member or mechanism may be added in order to block the light in the prescribed wavelength range, whereby the structure of the organic electroluminescent device itself is simplified for implementing a thin-film device. Further, the organic compound layer including the light blocking layer is also effectively applicable to a top emission structure.

The organic electroluminescent device may further comprise a light-transmitting substrate, and the substrate may include the light blocking layer. In this case, light generated by the light emitting layer is transmitted through the light-transmitting substrate and taken out from the organic electroluminescent device, while the light-transmitting substrate prevents external light in the prescribed wavelength range from entering the light emitting layer. Thus, no specific member or mechanism may be added in order to block the light in the prescribed wavelength range, whereby the structure of the organic electroluminescent device itself is simplified for implementing a thin-film device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a graph showing the relation between electromotive force in optical power generation of organic electroluminescent devices and the wavelengths of incident light;

FIG. 2 is a graph showing the relation between optical absorption wavelengths and absorption intensity of Alq and NPB;

FIG. 3 is a schematic sectional view showing an exemplary organic EL device according to a first embodiment of the present invention;

FIG. 4 is a schematic sectional view showing another exemplary organic EL device according to the first embodiment;

FIG. 5 is a schematic sectional view showing an exemplary organic EL device according to a second embodiment of the present invention;

FIG. 6 is a schematic sectional view showing an exemplary organic EL device according to a third embodiment of the present invention;

FIG. 7 is a schematic sectional view showing an exemplary organic EL device according to a fourth embodiment of the present invention;

FIG. 8 is a schematic sectional view showing an exemplary organic EL device according to a fifth embodiment of the present invention;

FIG. 9 is a schematic sectional view showing an exemplary organic EL device according to a sixth embodiment of the present invention;

FIG. 10 is a schematic sectional view showing an exemplary organic EL device according to a seventh embodiment of the present invention;

FIG. 11 is a schematic sectional view showing an exemplary organic EL device according to an eighth embodiment of the present invention;

FIG. 12 is a schematic plan view showing an exemplary organic EL display employing organic EL devices identical to the organic EL device according to the eighth embodiment;

FIG. 13 is a sectional view of the organic EL display taken along the line A-A in FIG. 12;

FIG. 14 is a graph showing light transmittance values of various filters employed in Inventive Examples;

FIG. 15 is a graph showing changes of drive voltages for organic EL devices according to Inventive Examples and comparative example; and

FIG. 16 is a graph showing changes of luminance values of organic EL devices according to Inventive Examples and comparative example.

### DESCRIPTION OF THE PREFERRED EMBODIMENTS

Organic electroluminescent (hereinafter abbreviated as EL) devices according to first to ninth embodiments of the present invention are now described.

### First Embodiment

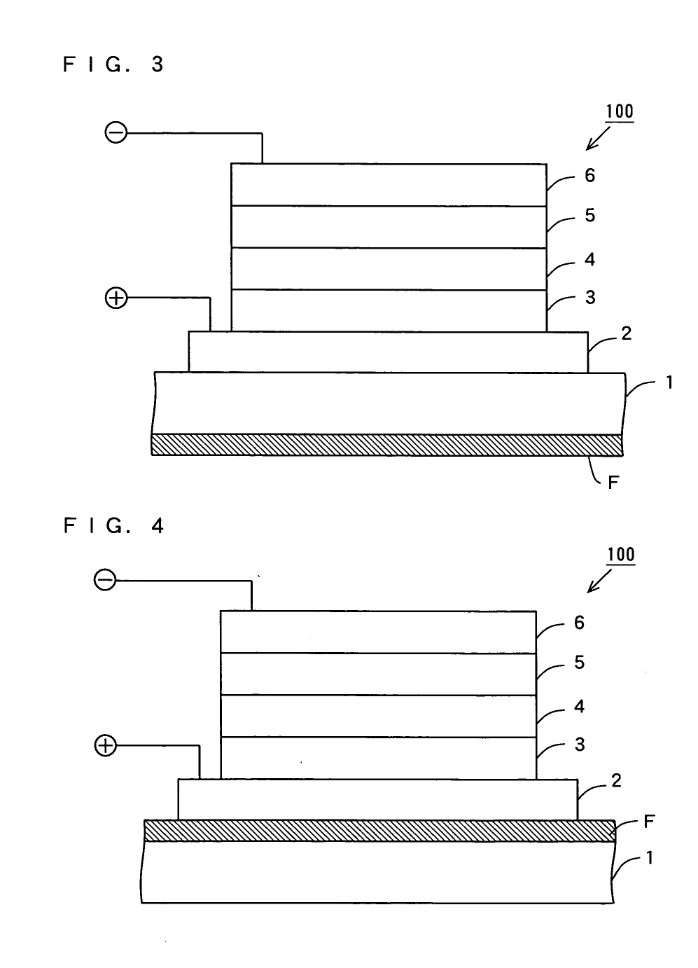

FIG. 3 is a schematic sectional view showing an exemplary organic EL device 100 according to the first embodiment. The organic EL device 100 according to the first embodiment comprises a transparent substrate 1, a hole injection electrode 2, an electron-donating organic compound layer 3, a light emitting layer 4, an electron-accepting organic compound layer 5, an electron injection electrode 6 and a filter F.

As shown in FIG. 3, the filter F is integrally formed on the under surface of the transparent substrate 1, while the hole injection electrode 2, the electron-donating organic compound layer 3, the light emitting layer 4, the electron-accepting organic compound layer 5 and the electron injection electrode 6 are successively stacked on the transparent substrate 1.

The transparent substrate 1 consists of a transparent material such as glass or plastic. The hole injection electrode 2 is a transparent electrode consisting of a metallic compound such as titanium oxide, zinc oxide, tin oxide, indium oxide or indium-tin oxide (hereinafter abbreviated as ITO), a metal such as silver, or an alloy. The electron injection electrode 6 is a transparent, semitransparent or opaque electrode consisting of a metallic compound such as lithium compound, calcium compound or ITO, a metal such as silver, aluminum, indium or magnesium, or an alloy.

The electron-donating organic compound layer 3, the light emitting layer 4 and the electron-accepting organic compound layer 5 consist of an organic material such as Alq having the molecular structure expressed in the above formula (1) or NPB having the molecular structure expressed in the above formula (2), for example.

The filter F blocks transmission of light having a specific wavelength. In the following description, the wording “blocking transmission of light” is not restricted to a case of blocking transmission of light by 100% (transmittance: 0%) but also includes a case of blocking transmission of partial light while allowing transmission of the remaining light (transmittance: greater than 0% and less than 100%).

The filter F may be prepared from a material such as a benzophenone-based, benzotriazole-based, oxalic anilide-based, cyanoacrylate-based or triazine-based organic compound or an inorganic compound such as titanium oxide, zinc oxide, tin oxide or indium oxide, for example. When the filter F is prepared from an inorganic compound, wavelength light blocked by the filter F can be changed by adding a slight quantity of metal such as nickel, iron, manganese or cobalt to the filter F. The wavelength light blocked by the filter F is described later.

The filter F is integrally formed on the transparent substrate 1 by application, vapor deposition, printing or bonding. Thus, the method of forming the filter F on the transparent substrate 1 is not particularly restricted so far as the former is integrated with the latter.

The filter F, integrally formed on the lower surface of the transparent substrate 1 in the above description, may alternatively be integrally formed on the upper surface of the transparent substrate 1. In this case, the hole injection electrode 2, the electron-donating organic compound layer 3, the light emitting layer 4, the electron-accepting organic compound layer 5 and the electron injection electrode 6 are successively stacked on the filter F, as shown in FIG. 4.

The structure of the organic EL device 100 according to the first embodiment is not restricted to the above examples but may be modified in various ways. For example, only the electron-donating organic compound layer 3 and the electron-accepting organic compound layer 5 may be provided between the hole injection electrode 2 and the electron injection electrode 6. In this case, a luminescent dopant is added to at least either the electron-accepting organic compound layer 5 or the electron-donating organic compound layer 3.

Thus, the organic EL device 100 may be provided with only the light emitting layer 4 and the electron-accepting organic compound layer 5 or only the light emitting layer 4 and the electron-donating organic compound layer 3 by adding the luminescent dopant to at least either the electron-accepting organic compound layer 5 or the electron-donating organic compound layer 3.

Further, a plurality of organic compound layers such as a hole blocking layer and an electron transport layer may be provided as the electron-accepting organic compound layer 5, while a plurality of organic compound layers such as a hole injection layer and a hole transport layer may be provided as the electron-donating organic compound layer 3.

When a drive voltage is applied between the hole injection electrode 2 and the electron injection electrode 6 of the organic EL device 100, the light emitting layer 4 emits light. The light emitted in the light emitting layer 4 is taken out through the electron-donating organic compound layer 3, the hole injection electrode 2, the transparent substrate land the filter F.

External light enters the organic compound layers 3 of the organic EL device 100 through the filter F and the transparent substrate 1. In this case, the filter F blocks transmission of specific wavelength light. The wavelength light blocked by the filter F is decided as follows:

When specific wavelength light enters the organic compound layers 3 and 5 in the organic EL device 100, the organic EL device 100 generates electromotive force (optical power generation). The electromotive force generated in this manner depends on the wavelength of the entering light (optical wavelength dependency).

Thus, the wavelength light blocked by the filter F is decided on the basis of the wavelength of light causing the maximum electromotive force (hereinafter referred to as the maximum electromotive wavelength). Therefore, the wavelength light blocked by the filter F is preferably decided by measuring optical wavelength dependency of the prepared organic EL device 100.

The degree of the filter F blocking transmission of light is expressed by transmittance. In the following description, the term transmittance indicates the degree of transmission of light with respect to total light (100%) entering the filter F. Therefore, the filter F is selected on the basis of light transmittance at various wavelengths.

The filter F according to the first embodiment preferably has transmittance lower than that on the long-wavelength side in the wavelength range shorter than a wavelength longer by 50 nm than the maximum electromotive wavelength of the organic EL device 100. Thus, the light emitted in the light emitting layer 5 is effectively taken out.

The filter F may have transmittance lower than that on the long-wavelength side beyond the wavelength longer by 50 nm than the maximum electromotive wavelength of the organic EL device 100 in the wavelength range of a wavelength shorter by 50 nm than the maximum electromotive wavelength up to the wavelength longer by 50 nm. In this case, the filter F has the maximum transmittance in the range on the long-wavelength side beyond the wavelength longer by 50 nm than the maximum electromotive force. Thus, the light emitted in the light emitting layer 5 is further effectively taken out.

When the maximum electromotive wavelength is 380 nm as a result of measurement of the optical wavelength dependency of the organic EL device 100, for example, the filter F preferably has transmittance of not more than 80% in the wavelength range shorter than 430 nm. In this case, the filter F preferably has transmittance higher than 80% in the wavelength range longer than 430 nm. The filter F may have transmittance of not more than 80% in the wavelength range of 330 nm to 380 nm.

Further, the filter F according to the first embodiment preferably has transmittance lower than that on the long-wavelength side in the wavelength range shorter than a wavelength longer by 100 nm than the maximum electromotive wavelength of the organic EL device 100. Thus, the light emitted in the light emitting layer 5 is effectively taken out.

The filter F may have transmittance lower than that on the long-wavelength side beyond the wavelength longer by 100 nm than the maximum electromotive wavelength of the organic EL device 100 in the wavelength range from the wavelength shorter by 100 nm than the maximum electromotive wavelength to the wavelength longer by 50 nm. In this case, the filter F has the maximum transmittance in the range on the long-wavelength side beyond the wavelength longer by 100 nm than the maximum electromotive wavelength. Thus, the light emitted in the light emitting layer 5 is further effectively taken out.

When the maximum electromotive wavelength is 380 nm as a result of measurement of the optical wavelength dependency of the organic EL device 100, for example, the filter F preferably has transmittance of not more than 80% in the wavelength range shorter than 480 nm. In this case, the filter F preferably has transmittance higher than 80% in the wavelength range longer than 480 nm. The filter F may have transmittance of not more than 80% in the wavelength range of 280 nm to 380 nm.

In the organic EL device 100 according to the first embodiment, the filter F blocks incidence of specific wavelength light in the electron-donating organic compound layer 3, the light emitting layer 4 and the electron-accepting organic compound layer 5. Thus, optical power generation of the organic EL device 100 is so suppressed as to suppress alternation in the vicinity of the interfaces between the hole injection electrode 2 and the electron-donating organic compound layer 3 and between the electron injection electrode 6 and the electron-accepting organic compound layer 5. Consequently, an increase of the drive voltage for attaining constant luminance is sufficiently reduced.

### Second Embodiment

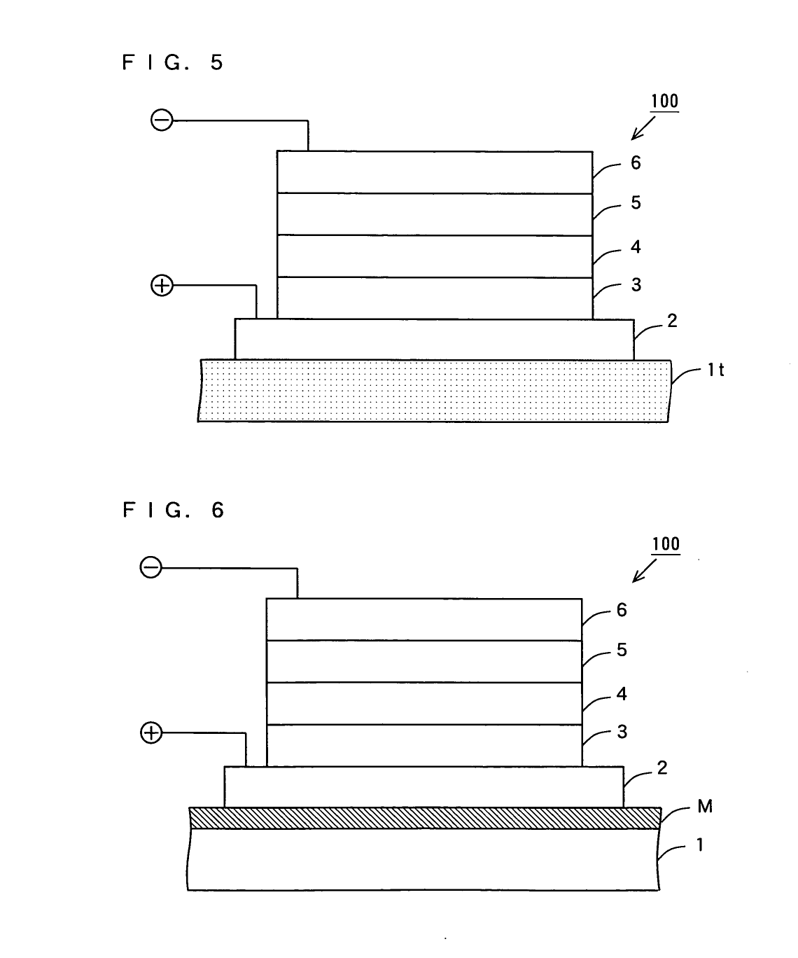

FIG. 5 is a schematic sectional view showing an exemplary organic EL device 100 according to the second embodiment. The organic EL device 100 according to the second embodiment is similar in structure to the organic EL device 100 according to the first embodiment, except the following point:

The organic EL device 100 according to the second embodiment employs a transparent substrate 1t blocking transmission of specific wavelength light in place of the transparent substrate 1 and the filter F in the organic EL device 100 according to the first embodiment. The transparent substrate 1t is prepared by adding a proper quantity of inorganic compound such as titanium oxide, zinc oxide, tin oxide or indium oxide to a glass substrate, for example.

The wavelength of light to be blocked by the transparent substrate it is decided on the basis of the maximum electromotive wavelength of the organic EL device 100, similarly to the first embodiment.

In the organic EL device 100 according to the second embodiment, the transparent substrate 1t blocks transmission of the specific wavelength light. Thus, optical power generation of the organic EL device 100 is so suppressed as to suppress alternation in the vicinity of the interfaces between a hole injection electrode 2 and an electron-donating organic compound layer 3 and between an electron injection electrode 6 and an electron-accepting organic compound layer 5. Consequently, an increase of a drive voltage for attaining constant luminance is sufficiently reduced.

The transparent substrate 1t so blocks transmission of the specific wavelength light that the organic EL device 100 requires no structure such as a filter for blocking the specific wavelength light. Thus, the structure of the organic EL device 100 itself is simplified for implementing a thin-film device.

### Third Embodiment

FIG. 6 is a schematic sectional view showing an exemplary organic EL device 100 according to the third embodiment. The organic EL device 100 according to the third embodiment is similar in structure to the organic EL device 100 according to the first embodiment, except the following point:

In the organic EL device 100 according to the third embodiment, a thin film M blocking transmission of specific wavelength light is evaporated to the upper surface of a transparent substrate 1 in place of the filter F in the organic EL device 100 according to the first embodiment.

The thin film M may be prepared from a material such as a benzophenone-based, benzotriazole-based, oxalic anilide-based, cyanoacrylate-based or triazine-based organic compound or an inorganic compound such as titanium oxide, zinc oxide, tin oxide or indium oxide, for example. When the thin film M is prepared from an inorganic compound, wavelength light blocked by the thin film M can be changed by adding a slight quantity of metal such as nickel, iron, manganese or cobalt to the thin film M.

The wavelength light blocked by the thin film M is decided on the basis of the maximum electromotive wavelength of the organic EL device 100, similarly to the first embodiment.

In the organic EL device 100 according to the third embodiment, the thin film M blocks the specific wavelength light. Thus, optical power generation of the organic EL device 100 is so suppressed as to suppress alternation in the vicinity of the interfaces between a hole injection electrode 2 and an electron-donating organic compound layer 3 and between an electron injection electrode 6 and an electron-accepting organic compound layer 5. Consequently, an increase of a drive voltage for attaining constant luminance is sufficiently reduced.

The thin film M so blocks transmission of the specific wavelength light that the organic EL device 100 requires no structure such as a filter for blocking transmission of the specific wavelength light. Thus, the organic EL device 100 is reduced in thickness.

### Fourth Embodiment

FIG. 7 is a schematic sectional view showing an exemplary organic EL device 100 according to the fourth embodiment. The organic EL device 100 according to the fourth embodiment is similar in structure to the organic EL device 100 according to the first embodiment, except the following point:

The organic EL device 100 according to the fourth embodiment employs a hole injection electrode 2t blocking transmission of specific wavelength light in place of the hole injection electrode 2 and the filter F in the organic EL device 100 according to the first embodiment.

The hole injection electrode 2t is prepared by adding a slight quantity of metal such as nickel, iron, manganese or cobalt to a hole injection electrode identical to the hole injection electrode 2 according to the first embodiment. Thus, the wavelength light blocked by the hole injection electrode 2t can be changed by adding a slight quantity of the aforementioned metal.

The wavelength of the light to be blocked by the hole injection electrode 2t is decided on the basis of the maximum electromotive wavelength of the organic EL device 100, similarly to the first embodiment.

In the organic EL device 100 according to the fourth embodiment, the hole injection electrode 2t blocks transmission of the specific wavelength light. Thus, optical power generation of the organic EL device 100 is so suppressed as to suppress alternation in the vicinity of the interfaces between the hole injection electrode 2t and an electron-donating organic compound layer 3 and between an electron injection electrode 6 and an electron-accepting organic compound layer 5. Consequently, an increase of a drive voltage for attaining constant luminance is sufficiently reduced.

The hole injection electrode 2t so blocks transmission of the specific wavelength light that the organic EL device 100 requires no structure such as a filter for blocking transmission of the specific wavelength light. Thus, the structure of the organic EL device 100 itself is simplified for implementing a thin-film device.

### Fifth Embodiment

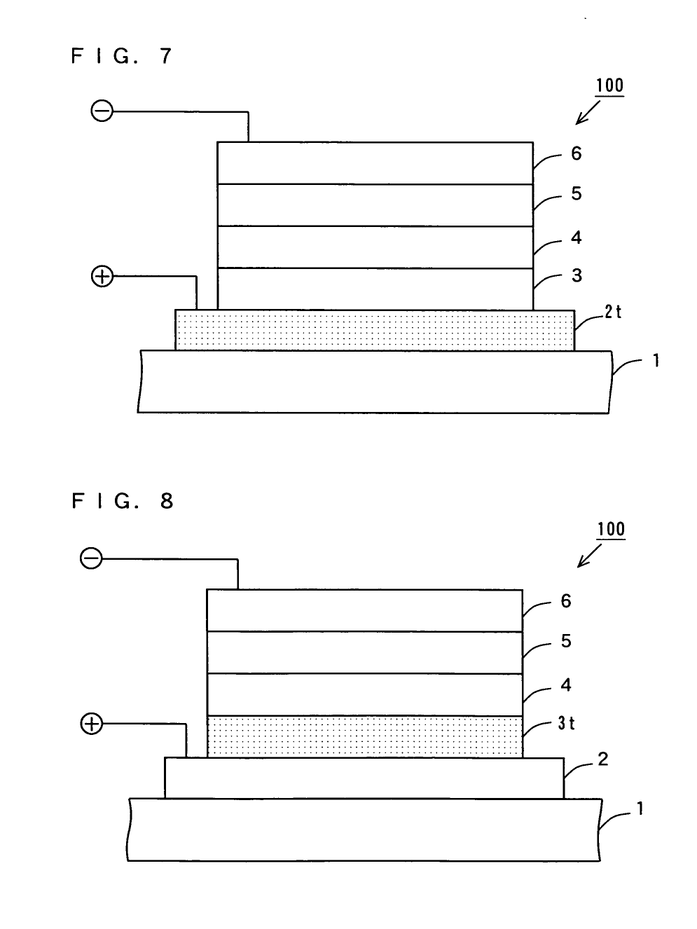

FIG. 8 is a schematic sectional view showing an exemplary organic EL device 100 according to the fifth embodiment. The organic EL device 100 according to the fifth embodiment is similar in structure to the organic EL device 100 according to the first embodiment, except the following point:

The organic EL device 100 according to the fifth embodiment employs an electron-donating organic compound layer 3t blocking transmission of specific wavelength light in place of the electron-donating organic compound layer 3 and the filter F in the organic EL device 100 according to the first embodiment.

The electron-donating organic compound layer 3t is prepared by adding a material blocking transmission of the specific wavelength light to an electron-donating organic compound layer identical to the electron-donating organic compound layer 3 according to the first embodiment. This material is prepared from a benzophenone-based, benzotriazole-based, oxalic anilide-based, cyanoacrylate-based or triazine-based organic compound, for example.

The electron-donating organic compound layer 3t is prepared by evaporating or applying the aforementioned organic compound simultaneously with formation of an electron-donating organic compound film on a hole injection electrode 2, for example.

The wavelength light to be blocked by the electron-donating organic compound layer 3t is decided on the basis of the maximum electromotive wavelength of the organic EL device 100, similarly to the first embodiment.

In the organic EL device 100 according to the fifth embodiment, the electron-donating organic compound layer 3t blocks transmission of the specific wavelength light. Thus, optical power generation of the organic EL device 100 is so suppressed as to suppress alternation in the vicinity of the interface between the hole injection electrode 2 and the electron-donating organic compound layer 3t. Consequently, an increase of a drive voltage for attaining constant luminance is sufficiently reduced.

The electron-donating organic compound layer 3t so blocks transmission of the specific wavelength light that the organic EL device 100 requires no structure such as a filter for blocking transmission of the specific wavelength light. Thus, the structure of the organic EL device 100 itself is simplified for implementing a thin-film device.

Further, the electron-donating organic compound layer 3t, so blocking transmission of the specific wavelength light as to suppress generation of carriers resulting from optical power generation, can also be effectively applied to an organic EL device having a structure (top emission structure) obtained by arranging a reflector on the side of the hole injection electrode 2 and forming an electron injection electrode 6 by a transparent electrode. The hole injection electrode 2 provided with the reflector may be formed by a semitransparent or opaque electrode. In this case, light emitted in a light emitting layer 4 is taken out through an electron-accepting organic compound layer 5 and the electron injection electrode 6. In the top emission structure, a transparent substrate 1 may not necessarily be transparent.

### Sixth Embodiment

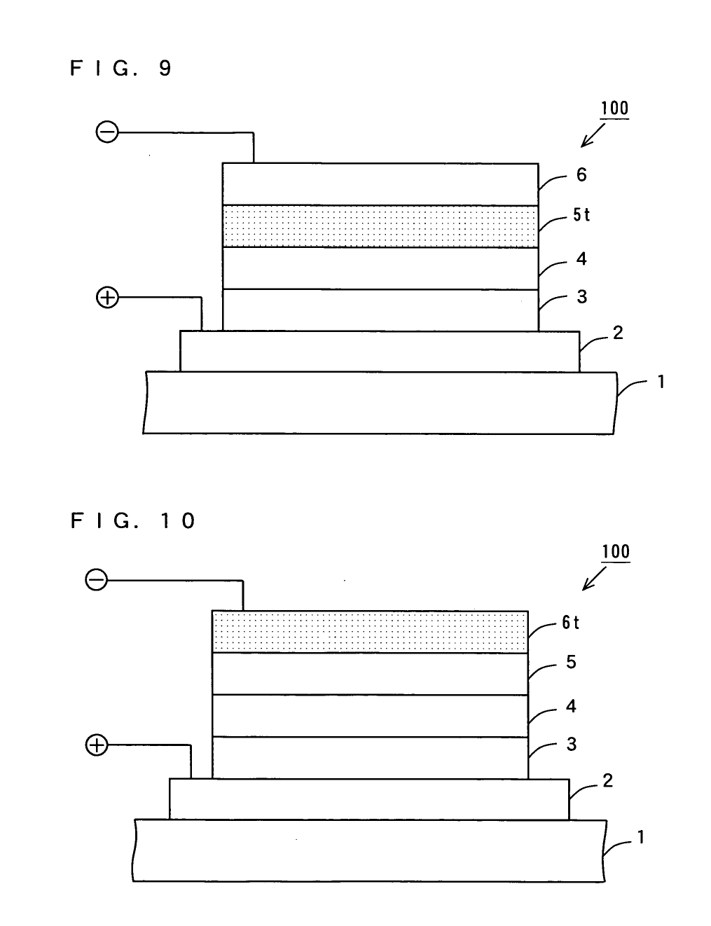

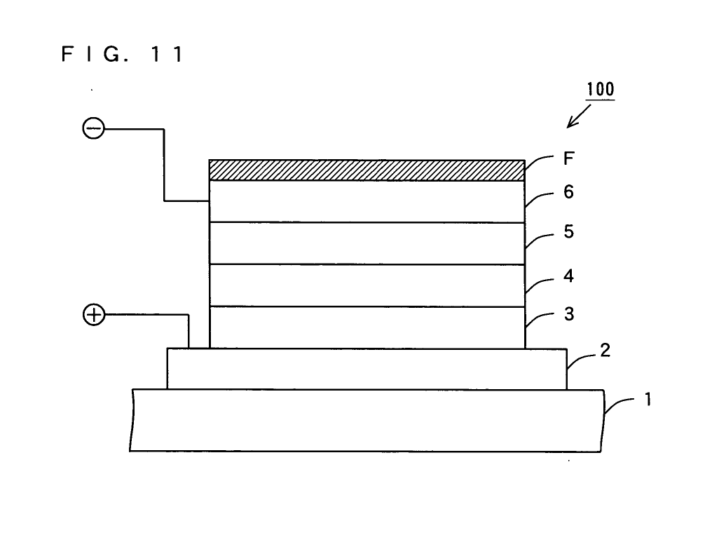

FIG. 9 is a schematic sectional view showing an exemplary organic EL device 100 according to the sixth embodiment. The organic EL device 100 according to the sixth embodiment is similar in structure to the organic EL device 100 according to the first embodiment, except the following point:

The organic EL device 100 according to the sixth embodiment employs an electron-accepting organic compound layer 5t blocking transmission of specific wavelength light in place of the electron-accepting organic compound layer 5 and the filter F in the organic EL device 100 according to the first embodiment.

The electron-accepting organic compound layer 5t is prepared by adding a material blocking transmission of the specific wavelength light to an electron-accepting organic compound layer identical to the electron-accepting organic compound layer 5 according to the first embodiment. This material is prepared from a benzophenone-based, benzotriazole-based, oxalic anilide-based, cyanoacrylate-based or triazine-based organic compound, for example.

The electron-accepting organic compound layer 5t is prepared by evaporating or applying the aforementioned organic compound simultaneously with formation of an electron-accepting organic compound film on a light emitting layer 4, for example.

The wavelength of the light to be blocked by the electron-accepting organic compound layer 5t is decided on the basis of the maximum electromotive wavelength of the organic EL device 100, similarly to the first embodiment.

A hole injection electrode 2 is a transparent, semitransparent or opaque electrode consisting of a metallic compound such as titanium oxide, zinc oxide, tin oxide, indium oxide or ITO, a metal such as silver, or an alloy. An electron injection electrode 6 is a transparent electrode consisting of a metallic compound such as lithium compound, calcium compound or ITO, a metal such as silver, aluminum, indium or magnesium, or an alloy. Thus, a top emission structure is implemented. When formed by a transparent electrode, the hole injection electrode 2 may be provided with a reflector. In the top emission structure, a transparent substrate 1 may not necessarily be transparent.

According to the aforementioned structure, light emitted in a light emitting layer 4 is taken out through the electron-accepting organic compound layer 5t and the electron injection electrode 6.

In the organic EL device 100 according to the sixth embodiment, the electron-accepting organic compound layer 5t blocks transmission of the specific wavelength light. Thus, optical power generation of the organic EL device 100 is so suppressed as to suppress alternation in the vicinity of the interfaces between the hole injection electrode 2 and the electron-donating organic compound layer 3 and between the electron injection electrode 6 and the electron-accepting organic compound layer 5t. Consequently, an increase of a drive voltage for attaining constant luminance is sufficiently reduced.

The electron-accepting organic compound layer 5t so blocks transmission of the specific wavelength light that the organic EL device 100 requires no structure such as a filter for blocking transmission of the specific wavelength light. Thus, the structure of the organic EL device 100 itself is simplified for implementing a thin-film device.

The organic EL device 100 according to the sixth embodiment is not restricted to the top emission structure but may alternatively be applied to a back emission structure with the hole injection electrode 2 formed by a transparent electrode, similarly to the first embodiment. In this case, the light emitted in the light emitting layer 4 is taken out through the electron-donating organic compound layer 3, the hole injection electrode 2, the transparent substrate 1 and a filter F.

### Seventh Embodiment

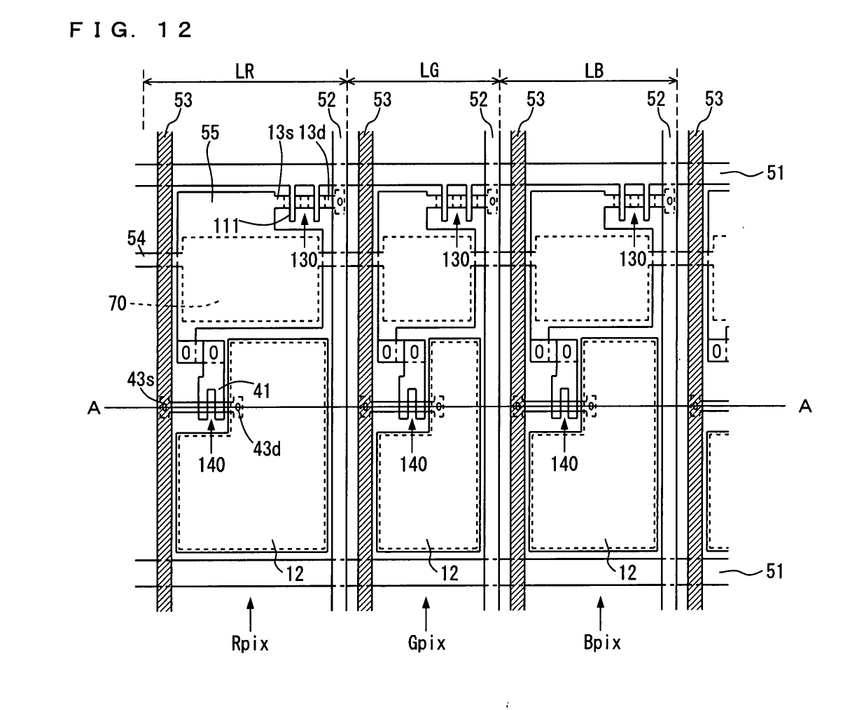

FIG. 10 is a schematic sectional view showing an exemplary organic EL device 100 according to the seventh embodiment. The organic EL device 100 according to the seventh embodiment is similar in structure to the organic EL device 100 according to the first embodiment, except the following point:

The organic EL device 100 according to the seventh embodiment employs an electron injection electrode 6t blocking transmission of specific wavelength light in place of the electron injection electrode 6 and the filter F in the organic EL device 100 according to the first embodiment.

The electron injection electrode 6t, which is a transparent electrode, is prepared by adding a slight quantity of metal such as nickel, iron, manganese or cobalt to an electron injection electrode identical to the electron injection electrode 6 according to the first embodiment. Thus, the wavelength light blocked by the electron injection electrode 6t can be changed by adding a slight quantity of the aforementioned metal.

The wavelength of the light to be blocked by the electron injection electrode 6t is decided on the basis of the maximum electromotive wavelength of the organic EL device 100, similarly to the first embodiment.

A hole injection electrode 2 is a transparent, semitransparent or opaque electrode consisting of a metallic compound such as titanium oxide, zinc oxide, tin oxide, indium oxide or ITO, a metal such as silver or an alloy. Thus, a top emission structure is implemented. When formed by a transparent electrode, the hole injection electrode 2 may be provided with a reflector. In the top emission structure, a transparent substrate 1 may not necessarily be transparent.

According to the aforementioned structure, light emitted in a light emitting layer 4 is taken out through an electron-accepting organic compound layer 5 and the electron injection electrode 6t.

In the organic EL device 100 according to the seventh embodiment, the electron injection electrode 6t blocks transmission of the specific wavelength light. Thus, optical power generation of the organic EL device 100 is so suppressed as to suppress alternation in the vicinity of the interfaces between the hole injection electrode 2 and an electron-donating organic compound layer 3 and between the electron injection electrode 6t and the electron-accepting organic compound layer 5. Consequently, an increase of a drive voltage for attaining constant luminance is sufficiently reduced.

The electron injection electrode 6t so blocks transmission of the specific wavelength light that the organic EL device 100 requires no structure such as a filter for blocking transmission of the specific wavelength light. Thus, the structure of the organic EL device 100 itself is simplified for implementing a thin-film device.

The organic EL device 100 according to the seventh embodiment is not restricted to the top emission structure but may alternatively be applied to a back emission structure with the hole injection electrode 2 formed by a transparent electrode, similarly to the first embodiment. In this case, the light emitted in the light emitting layer 4 is taken out through the electron-donating organic compound layer 3, the hole injection electrode 2, the transparent substrate 1 and a filter F.

### Eighth Embodiment

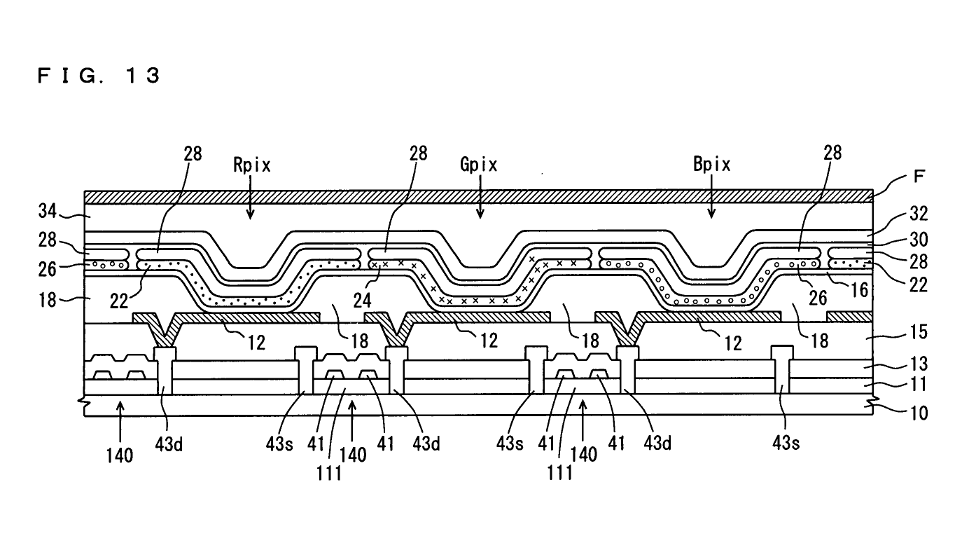

FIG. 11 is a schematic sectional view showing an exemplary organic EL device 100 according to the eighth embodiment. The organic EL device 100 according to the eighth embodiment is similar in structure to the organic EL device 100 according to the first embodiment, except the following point:

In the organic EL device 100 according to the eighth embodiment, a filter F similar to that according to the first embodiment is integrally formed on the upper surface of an electron injection electrode 6. The wavelength of light to be blocked by the filter F is decided on the basis of the maximum electromotive wavelength, similarly to the first embodiment.

A hole injection electrode 2 is a transparent, semitransparent or opaque electrode consisting of a metallic compound such as titanium oxide, zinc oxide, tin oxide, indium oxide or ITO, a metal such as silver, or an alloy. An electron injection electrode 6 is a transparent electrode consisting of a metallic compound such as lithium compound, calcium compound or ITO, a metal such as silver, aluminum, indium or magnesium, or an alloy. Thus, a top emission structure is implemented. When formed by a transparent electrode, the hole injection electrode 2 may be provided with a reflector. In the top emission structure, a transparent substrate 1 may not necessarily be transparent.

According to the aforementioned structure, light emitted in a light emitting layer 4 is taken out through an electron-accepting organic compound layer 5, the electron injection electrode 6 and the filter F.

In the organic EL device 100 according to the eighth embodiment, the filter F blocks transmission of the specific wavelength light. Thus, optical power generation of the organic EL device 100 is so suppressed as to suppress alternation in the vicinity of the interfaces between the hole injection electrode 2 and the electron-donating organic compound layer 3 and between the electron injection electrode 6 and the electron-accepting organic compound layer 5. Consequently, an increase of a drive voltage for attaining constant luminance is sufficiently reduced.

In each of the aforementioned first to eighth embodiments, the light emitting layer 4 may emit light of green, blue or red. Further, the light emitting layer 4 may be formed by a plurality of light emitting layers emitting light components having different wavelengths.

For example, the light emitting layer 4 may be formed by two light emitting layers emitting orange and blue light components respectively. In this case, the organic EL device 100 can generate white light or the like. When an organic EL device capable of obtaining white emission is provided with red, green and blue filters, display of three primary colors of light (RGB display) is enabled for implementing full-color display.

### Ninth Embodiment

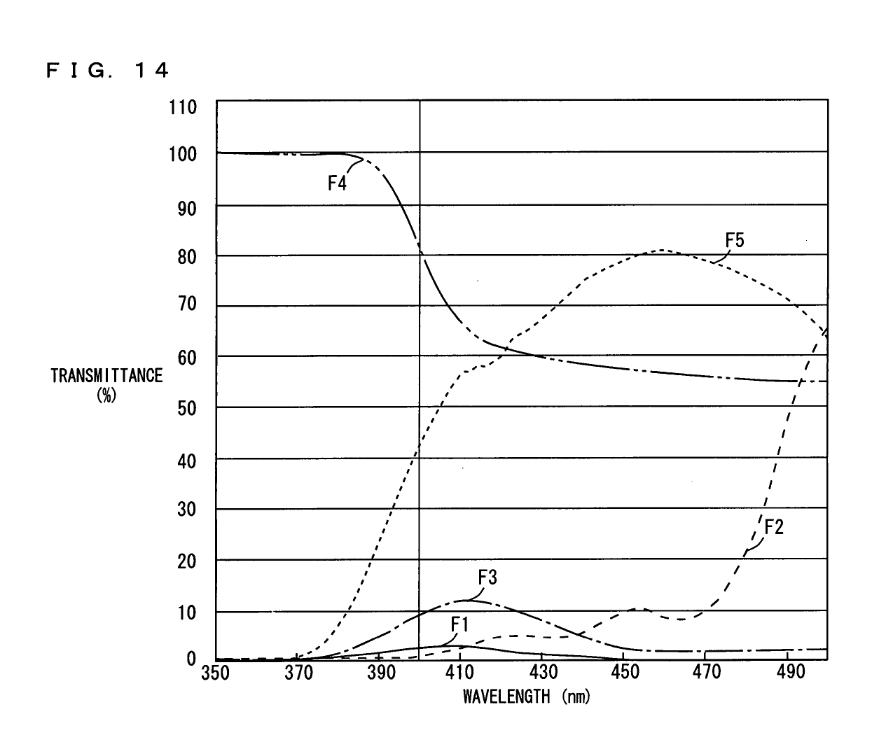

FIG. 12 is a schematic plan view showing an example of an organic EL display device using the organic EL device according to the first embodiment, and FIG. 13 is a cross-sectional view taken along a line A-A in the organic EL display device shown in FIG. 12.

In the organic EL display device shown in FIGS. 12 and 13, a pixel emitting red light (hereinafter referred to an R pixel) Rpix, a pixel emitting green light (hereinafter referred to as a G pixel) Gpix, and a pixel emitting blue light (hereinafter referred to as a B pixel) Bpix are arranged in the form of a matrix. In the following description, each of the R pixel Rpix, the G pixel Gpix, and the B pixel Bpix corresponds to the organic EL device 100 according to the eighth embodiment.

In the following description, a glass substrate 10, an active layer 11, an interlayer insulating film 13, a first flattening layer 15, a first TFT 130, and a second TFT 140 correspond to the transport substrate 1 shown in FIG. 11 according to the eighth embodiment, a hole transport layer 16 corresponds to the electron-donating organic compound layer 3 shown in FIG. 11, a red light emitting layer 22, a green light emitting layer 24, and a blue light emitting layer 26 correspond to the light emitting layer 4 shown in FIG. 11, and an electron transport layer 28 corresponds to the electron-accepting organic compound layer 5 shown in FIG. 11.

In FIG. 12, the R pixel Rpix, the G pixel Gpix, and the B pixel Bpix are provided in this order from the left.

The structures of the pixels are the same in a plan view. One of the pixels is formed in a region enclosed by two gate signal lines 51 extending in a row direction and two drain signal lines (data lines) 52 extending in a column direction. In the region of each of the pixels, an n-channel type first TFT 130 which is a switching element is formed in the vicinity of an intersection of the gate signal line 51 and the drain signal line 52, and a p-channel type second TFT 140 for driving the organic EL device is formed in the vicinity of the center of the region. Further, an auxiliary capacitance 70, and a hole injection electrode 12 composed of ITO are formed in the region of each of the pixels. The organic EL device is formed in an island shape in a region of the hole injection electrode 12.

The first TFT 130 has its drain connected to the drain signal line 52 through a drain electrode 13d, and the first TFT 130 has its source connected to an electrode 55 through a source electrode 13s. A gate electrode 111 in the first TFT 130 extends from a gate signal line 51.

The auxiliary capacitance 70 comprises an SC (Status/Command) line 54 receiving a power supply voltage Vsc and an electrode 55 integrated with the active layer 11 (see FIG. 5).

The second TFT 140 has its drain connected to the hole injection electrode 12 in the organic EL device through a drain electrode 43d, and the second TFT 140 has its source connected to a power supply line 53 extending in a column direction through a source electrode 43s. A gate electrode 41 in the second TFT 140 is connected to the electrode 55.

The width LR of the R pixel Rpix, the width LG of the G pixel Gpix, and the width LB of the B pixel Bpix are respectively set such that the amounts of lights emitted by the R pixel Rpix, the G pixel Gpix, and the B pixel Bpix are equal in consideration of the luminous efficiencies of the organic EL devices. In the present embodiment, the width LR of the R pixel Rpix is 75.5 μm, the width LG of the G pixel Gpix is 56.6 μm, and the width LB of the B pixel Bpix is 66 μm.

As shown in FIG. 5, the active layer 11 composed of polycrystalline silicon or the like is formed on the glass substrate 10, and a part of the active layer 11 is the second TFT 140 for driving the organic EL device. A gate electrode 41 having a double gate structure is formed on the active layer 11 through a gate oxide film (not shown), and the interlayer insulating film 13 and the first flattening layer 15 are formed on the active layer 11 so as to cover the gate electrode 41. Acrylic resin, for example, can be used as a material for the first flattening layer 15. The transparent hole injection electrode 12 is formed for each of the pixels on the first flattening layer 15, and an insulative second flattening layer 18 is formed on the first flattening layer 15 so as to cover the hole injection electrode 12.

The second TFT 140 is formed under the second flattening layer 18. Here, the second flattening layer 18 is formed not on the whole surface of the hole injection electrode 12 but locally so as to cover a region having the second TFT 140 formed therein and so as not to disconnect the hole injection electrode 12 or each of organic material layers, described later, in the shape of the second flattening layer 18.

The hole transport layer 16 is formed on the overall region so as to cover the hole injection electrode 12 and the second flattening layer 18.

The striped red light emitting layer 22, the striped green light emitting layer 24, and the striped blue light emitting layer 26 each extending in a column direction are respectively formed in the areas, on the hole transport layer 16, of the R pixel Rpix, the G pixel Gpix, and the B pixel Bpix.

The boundaries among the striped red light emitting layer 22, green light emitting layer 24, and blue light emitting layer 26 are provided in a region, parallel to the glass substrate 10, on a surface of the second flattening layer 18.

The striped electron transport layers 28 extending in a column direction are respectively formed on the red light emitting layer 22, the green light emitting layer 24, and the blue light emitting layer 26 in the R pixel Rpix, the G pixel Gpix, and the B pixel Bpix.

The light emitting layers 22, 24, and 26 and the electron transport layers 28 in the R pixel Rpix, the G pixel Gpix, and the B pixel Bpix are continuously formed for each color in a multi-chamber type organic EL manufacturing apparatus comprising a plurality of evaporation chambers. That is, the red light emitting layer 22 and the electron transport layer 28 in the R pixel Rpix are continuously formed using a common mask in the first evaporation chamber. The green light emitting layer 24 and the electron transport layer 28 in the G pixel Gpix are continuously formed using a common mask in the second evaporation chamber. Further, the blue light emitting layer 26 and the electron transport layer 28 in the B pixel Bpix are continuously formed using a common mask in the third evaporation chamber. Consequently, the boundaries among the electron transport layers 28 are respectively provided so as to be superimposed on the boundaries among the red light emitting layer 22, the green light emitting layer 24, and the blue light emitting layer 26.

The light emitting layers 22, 24, and 26 and the electron transport layers 28 are respectively formed for the colors in the different evaporation chambers, thereby avoiding cross-contamination of a dopant produced in a case where the light emitting layers 22, 24, and 26 of three types and the electron transport layers 28 are formed in the same evaporation chamber.

Furthermore, a lithium fluoride layer 30 and an electron injection electrode 32 which are common to the electron transport layers 28 are successively formed on each of the electron transport layers 28. A protective film 34 composed of resin or the like is formed on the electron injection electrode 32, while a filter F is provided on the protective layer 34.

In the above-mentioned organic EL display device, when a selection signal is outputted to the gate signal line 51, the first TFT 130 is turned on, so that the auxiliary capacitance 70 is charged depending on a voltage value (a data signal) fed to the drain signal line 52 at that time. The gate electrode 41 in the second TFT 140 receives a voltage corresponding to a charge given to the auxiliary capacitance 70. Consequently, a current supplied to the organic EL device from the power supply line 53 is controlled, so that the organic EL device emits light at a luminance corresponding to the supplied current.

In the organic EL display device according to the present embodiment, a video can be displayed by thus arranging the organic EL devices 100 according to the eighth embodiment in the form of a matrix and individually setting their luminescent colors as the R pixel Rpix, the G pixel Gpix, and the B pixel Bpix.

The filter F blocks transmission of specific wavelength light entering the organic EL display from above, whereby optical power generation of the R, G and B pixels Rpix, Gpix and Bpix (each corresponding to the organic EL device 100 according to the eighth embodiment) is so suppressed as to suppress alternation in the vicinity of the interfaces between the hole injection electrodes 12 and the hole transport layers 16 and between the electron injection electrode 32, the lithium fluoride layer 30 and the electron transport layer 28. Consequently, an increase of a drive voltage for attaining constant luminance is sufficiently reduced.

In the aforementioned first to ninth embodiments of the present invention, the light emitting layers 4, the red light emitting layer 22, the green light emitting layer 24 and the blue light emitting layer 26 correspond to the light emitting layer, the maximum electromotive wavelengths correspond to the specific wavelength, the filters F, the transparent substrate 1t, the thin film M, the hole injection electrode 2t, the electron-donating organic compound layer 3t, the electron-accepting organic compound layer 5t and the electron injection electrode 6t correspond to the light blocking layer, and the filters F correspond to the optical filter. The hole injection electrode 2t and the electron injection electrode 6t correspond to the light-transmitting electrode, the transparent substrate 1t corresponds to the light-transmitting substrate, and the electron-donating organic compound layers 3, the light emitting layers 4, the electron-accepting organic compound layers 5, the hole transport layers 16, the light emitting layers 4, the red light emitting layer 22, the green light emitting layer 24, the blue light emitting layer 26 and the electron transport layer 28 correspond to the organic compound layer.

On the basis of the first embodiment, organic EL devices according to Inventive Examples 1 to 5 were prepared for making researches as to deterioration of the organic EL devices resulting from incidence of light.

### INVENTIVE EXAMPLE 1

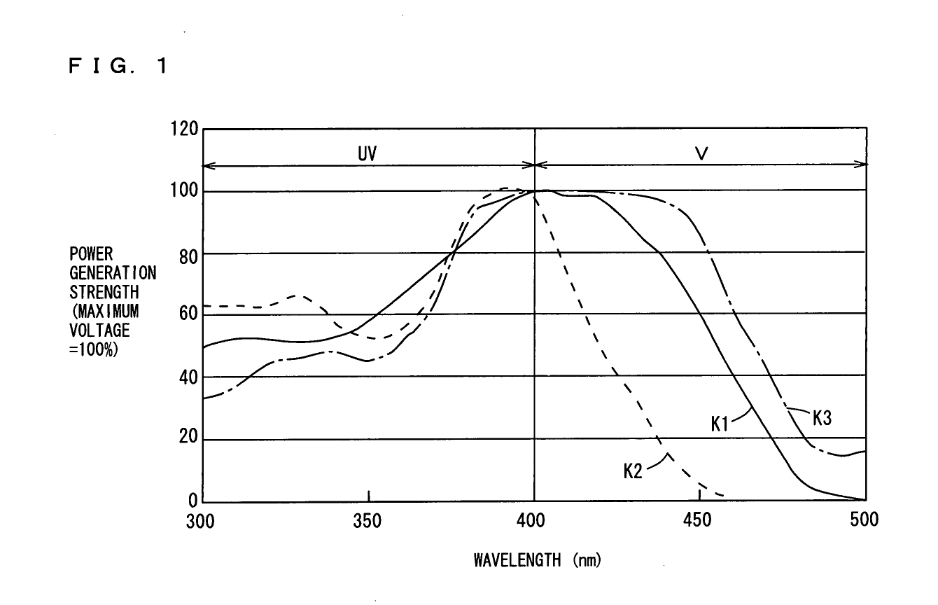

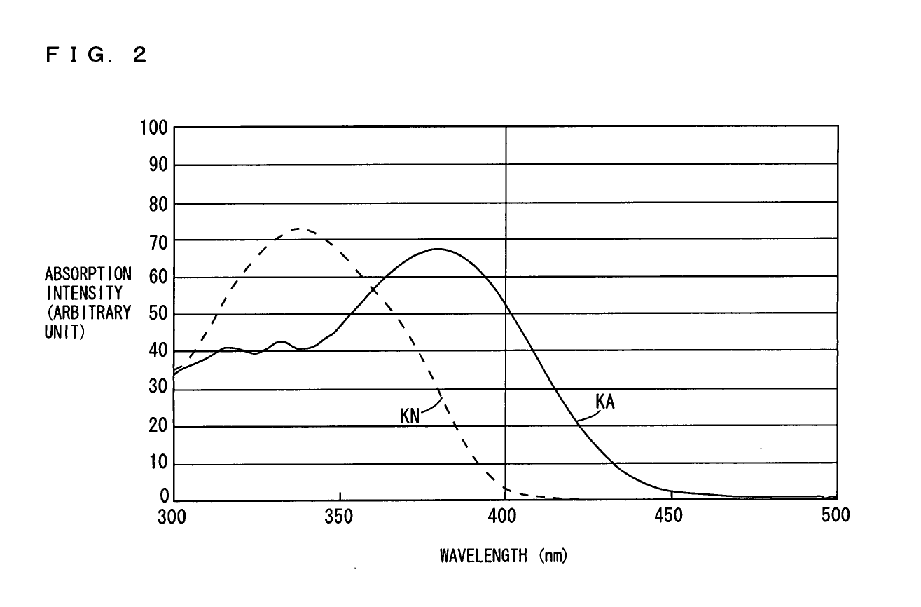

The organic EL device (white device) according to Inventive Example 1 was prepared by employing NPB and Alq for an electron-donating organic compound layer 3 and an electron-accepting organic compound layer 5 respectively in an organic EL device identical to the organic EL device 100 according to the first embodiment shown in FIG. 3. An light emitting layer 4 was prepared by stacking a red light emitting layer and a blue light emitting layer with each other. This organic EL device had a filter F1. The organic EL device having this structure exhibited an optical power generation characteristic identical to that shown by the solid line K1 in FIG. 1, and the maximum electromotive wavelength thereof was 400 nm.

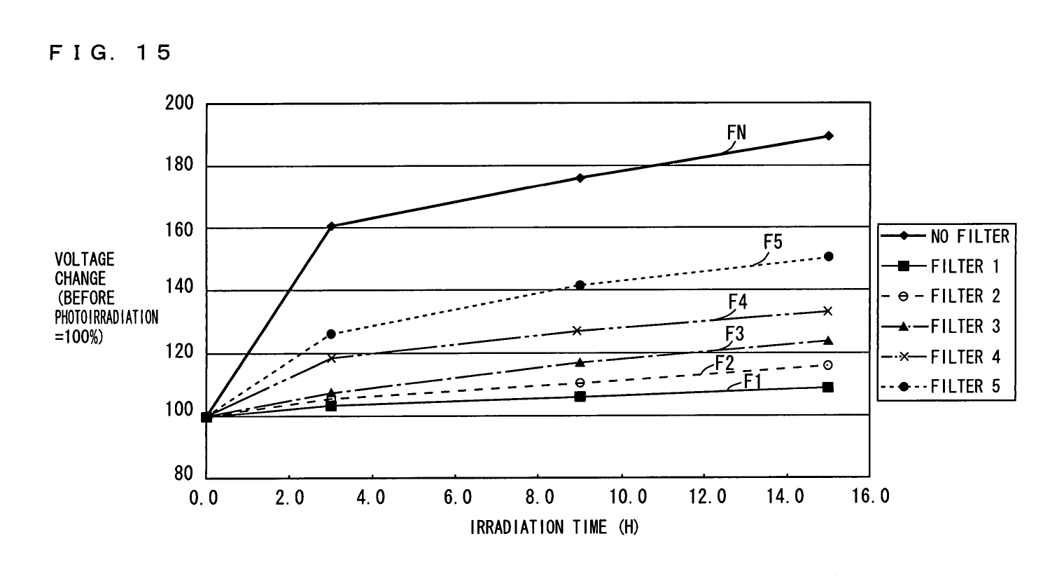

FIG. 14 is a graph showing light transmittance values of various filters employed for Inventive Examples. Referring to FIG. 14, the solid line F1 shows the light transmittance of the filter F1 of the organic EL device according to Inventive Example 1.

According to FIG. 14, the filter F1 exhibited extremely lower transmittance as compared with the remaining filters. In other words, the filter F1 exhibited transmittance of about 3% at the maximum in the wavelength rage of 350 nm to 500 nm. In this case, the wavelength of light was about 400 nm.

The filter F1 of the organic EL device according to Inventive Example 1 was continuously irradiated with light from a solar simulator (pseudo-sunlight generator) for 15 hours. This light was pseudo sunlight (30° C.: 1000 W/m²) having brightness equivalent to that of sunlight right on the equator.

Change of luminance was measured every prescribed time while change of a drive voltage was measured with a driving current of 2.0 mA. Table 1 shows the results of measurement.

TABLE 1

| | | | Rate of | |
|---|---|---|---|---|
| Irradiation | Luminance | Voltage | Luminance | Rate of |
| Time (H) | (cd/m2) | (V) | Change | Voltage Change |
| 0.0 | 2360 | 8.06 | 100% | 100% |
| 3.0 | 2330 | 8.33 | 99% | 103% |
| 9.0 | 2340 | 8.55 | 99% | 106% |
| 15.0 | 2280 | 8.78 | 97% | 109% |

### INVENTIVE EXAMPLE 2

The organic EL device (white device) according to Inventive Example 2 was similar in structure to the organic EL device according to Inventive Example 1, except a filter. The organic EL device according to Inventive Example 2 employed a filter F2. The organic EL device having this structure also exhibited an optical power generation characteristic identical to that shown by the solid line K1 in FIG. 1 similarly to the organic EL device according to Inventive Example 1, and the maximum electromotive wavelength thereof was 400 nm.

Referring to FIG. 14, the broken line F2 shows light transmittance of the filter F2 of the organic EL device according to Inventive Example 2. As shown in FIG. 14, the filter F2 exhibited transmittance of not more than about 10% in the wavelength range of 350 nm to about 470 nm. The transmittance of the filter F2 was abruptly increased in the wavelength range of about 470 nm to 500 nm. The filter F2 transmitted about 65% of light at the wavelength of 500 nm.

Similarly to Inventive Example 1, the filter F2 of the organic EL device according to Inventive Example 2 was continuously irradiated with light from the solar simulator (pseudo-sunlight generator) for 15 hours. This light was pseudo sunlight (30° C.: 1000 W/m²) having brightness equivalent to that of sunlight right on the equator.

Change of luminance was measured every prescribed time while change of a drive voltage was measured with a driving current of 2.0 mA. Table 2 shows the results of measurement.

TABLE 2

| | | | Rate of | |
|---|---|---|---|---|
| Irradiation | Luminance | Voltage | Luminance | Rate of |
| Time (H) | (cd/m2) | (V) | Change | Voltage Change |
| 0.0 | 2190 | 7.42 | 100% | 100% |
| 3.0 | 2180 | 7.84 | 100% | 106% |
| 9.0 | 2080 | 8.19 | 95% | 110% |
| 15.0 | 2150 | 8.60 | 98% | 116% |

### INVENTIVE EXAMPLE 3

The organic EL device (white device) according to Inventive Example 3 was similar in structure to the organic EL device according to Inventive Example 1, except a filter.

The organic EL device according to Inventive Example 3 employed a filter F3. The organic EL device having this structure also exhibited an optical power generation characteristic identical to that shown by the solid line K1 in FIG. 1 similarly to the organic EL device according to Inventive Example 1, and the maximum electromotive wavelength thereof was 400 nm.

Referring to FIG. 14, the one-dot chain line F3 shows light transmittance of the filter F3 of the organic EL device according to Inventive Example 3. As shown in FIG. 14, the filter F3 exhibited transmittance of about 12% at the maximum in the wavelength range of 350 nm to 500 nm. In this case, the wavelength of light was about 410 nm.

Similarly to Inventive Example 1, the filter F3 of the organic EL device according to Inventive Example 3 was continuously irradiated with light from the solar simulator (pseudo-sunlight generator) for 15 hours. This light was pseudo sunlight (30° C.: 1000 W/m²) having brightness equivalent to that of sunlight right on the equator.

Change of luminance was measured every prescribed time while change of a drive voltage was measured with a driving current of 2.0 mA. Table 3 shows the results of measurement.

TABLE 3

| | | | Rate of | |
|---|---|---|---|---|
| Irradiation | Luminance | Voltage | Luminance | Rate of |
| Time (H) | (cd/m2) | (V) | Change | Voltage Change |
| 0.0 | 2440 | 7.33 | 100% | 100% |
| 3.0 | 2430 | 7.87 | 100% | 107% |
| 9.0 | 2400 | 8.58 | 98% | 117% |
| 15.0 | 2380 | 9.08 | 98% | 124% |

### INVENTIVE EXAMPLE 4

The organic EL device (white device) according to Inventive Example 4 was similar in structure to the organic EL device according to Inventive Example 1, except a filter. The organic EL device according to Inventive Example 4 employed a filter F4. The organic EL device having this structure also exhibited an optical power generation characteristic identical to that shown by the solid line K1 in FIG. 1 similarly to the organic EL device according to Inventive Example 1, and the maximum electromotive wavelength thereof was 400 nm.

Referring to FIG. 14, the two-dot chain line F4 shows light transmittance of the filter F4 of the organic EL device according to Inventive Example 4. As shown in FIG. 14, the filter F4 exhibited transmittance of about 100% in the wavelength range of 350 nm to about 380 nm. The transmittance was abruptly reduced to about 60% in the wavelength range of about 380 nm to about 420 nm, and gradually reduced to about 55% in the wavelength range of about 420 nm to about 500 nm.

Similarly to Inventive Example 1, the filter F4 of the organic EL device according to Inventive Example 4 was continuously irradiated with light from the solar simulator (pseudo-sunlight generator) for 15 hours. This light was pseudo sunlight (30° C.: 1000 W/m²) having brightness equivalent to that of sunlight right on the equator.

Change of luminance was measured every prescribed time while change of a drive voltage was measured with a driving current of 2.0 mA. Table 4 shows the results of measurement.

TABLE 4

| | | | Rate of | |
|---|---|---|---|---|
| Irradiation | Luminance | Voltage | Luminance | Rate of |
| Time (H) | (cd/m2) | (V) | Change | Voltage Change |
| 0.0 | 2480 | 7.2 | 100% | 100% |
| 3.0 | 2440 | 8.53 | 98% | 118% |
| 9.0 | 2370 | 9.15 | 96% | 127% |
| 15.0 | 2320 | 9.58 | 94% | 133% |

### INVENTIVE EXAMPLE 5

The organic EL device (white device) according to Inventive Example 5 was similar in structure to the organic EL device according to Inventive Example 1, except a filter. The organic EL device according to Inventive Example 5 employed a filter F5. The organic EL device having this structure also exhibited an optical power generation characteristic identical to that shown by the solid line K1 in FIG. 1 similarly to the organic EL device according to Inventive Example 1, and the maximum electromotive wavelength thereof was 400 nm.

Referring to FIG. 14, the dotted line F5 shows light transmittance of the filter F5 of the organic EL device according to Inventive Example 5. As shown in FIG. 14, the filter F5 exhibited extremely low transmittance in the wavelength range of 350 nm to about 370 nm. The transmittance was increased to about 80% in the wavelength range of about 370 nm to about 460 nm, and gradually reduced to about 65% in the wavelength range of about 420 nm to about 500 nm.

Similarly to Inventive Example 1, the filter F5 of the organic EL device according to Inventive Example 5 was continuously irradiated with light from the solar simulator (pseudo-sunlight generator) for 15 hours. This light was pseudo sunlight (30° C.: 1000 W/m²) having brightness equivalent to that of sunlight right on the equator.

Change of luminance was measured every prescribed time while change of a drive voltage was measured with a driving current of 2.0 mA. Table 5 shows the results of measurement.

TABLE 5

| | | | Rate of | |
|---|---|---|---|---|
| Irradiation | Luminance | Voltage | Luminance | Rate of |
| Time (H) | (cd/m2) | (V) | Change | Voltage Change |
| 0.0 | 2440 | 6.83 | 100% | 100% |
| 3.0 | 2450 | 8.62 | 100% | 126% |
| 9.0 | 2330 | 9.65 | 95% | 141% |
| 15.0 | 2320 | 10.26 | 95% | 150% |

As hereinabove described, each of the filters F1 to F5 employed for the organic EL devices according to Inventive Examples 1 to 5 had transmittance of not more than 80% at the maximum electromotive wavelength (about 400 nm) of the organic EL device.

### COMPARATIVE EXAMPLE

The organic EL device according to comparative example was prepared by providing an organic EL device identical to the organic EL device (white device) according to Inventive Example 1 with no filter F1, for making a research as to deterioration of the organic E1 device resulting from entrance of light. The organic EL device having this structure also exhibited an optical power generation characteristic identical to that shown by the solid line K1 in FIG. 1 similarly to the organic EL device according to Inventive Example 1, and the maximum electromotive wavelength thereof was 400 nm.

A transparent substrate of the organic EL device according to comparative example was continuously irradiated with light from the solar simulator (pseudo-sunlight generator) for 15 hours. This light was pseudo sunlight (30° C.: 1000 W/m²) having brightness equivalent to that of sunlight right on the equator.

Change of luminance was measured every prescribed time while change of a drive voltage was measured with a driving current of 2.0 mA. Table 6 shows the results of measurement.

TABLE 6

| | | | Rate of | |
|---|---|---|---|---|
| Irradiation | Luminance | Voltage | Luminance | Rate of |
| Time (H) | (cd/m2) | (V) | Change | Voltage Change |
| 0.0 | 2400 | 6.76 | 100% | 100% |
| 3.0 | 2330 | 10.84 | 97% | 160% |
| 9.0 | 2270 | 11.9 | 95% | 176% |
| 15.0 | 2220 | 12.79 | 93% | 189% |

[Evaluation]

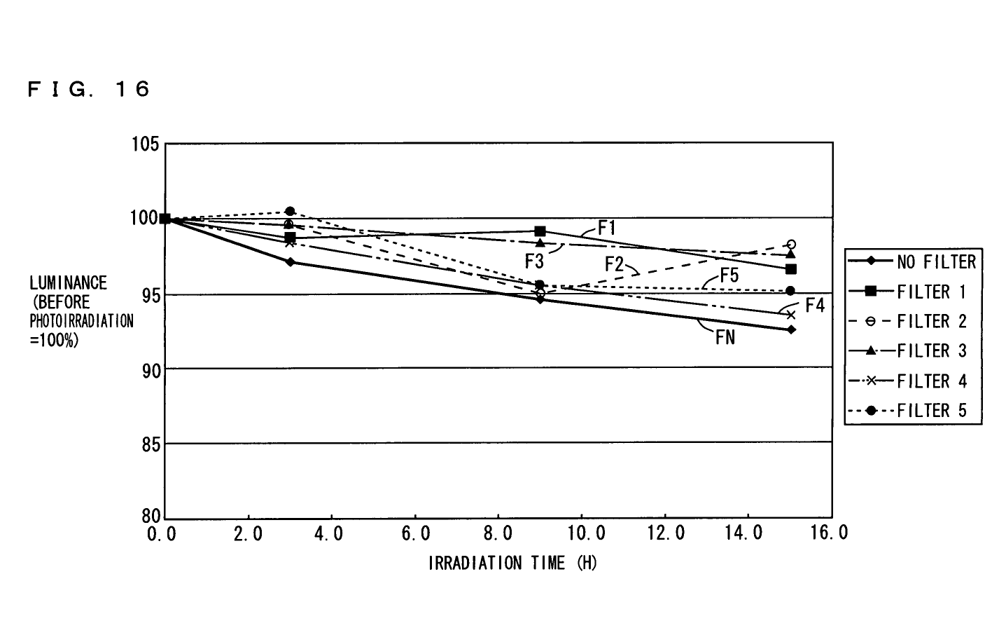

FIG. 15 is a graph showing changes of drive voltages for the organic EL devices according to Inventive Examples and comparative example. The axis of ordinate shows the rates of change (before photoirradiation: 100%) of the drive voltages, and the axis of abscissas shows times of continuous photoirradiation with the solar simulator.

Referring to FIG. 15, the solid line F1, the broken line F2, the one-dot chain line F3, the two-dot chain line F4, the dotted line F5 and the wide line FN show the changes of the drive voltages for the organic EL devices according to Inventive Examples 1 to 5 and comparative example respectively.

According to FIG. 15, the organic EL device according to comparative example provided with no filter exhibited an extremely large rate of change over 15 hours from irradiation starting. After a lapse of the irradiation time of 15 hours, the rate of change of the drive voltage was 89% with reference to the drive voltage before photoirradiation.

In the organic EL device according to Inventive Example 5, on the other hand, the rate of change was reduced over 15 hours from irradiation starting as compared with the organic EL device according to comparative example. After the lapse of the irradiation time of 15 hours, the rate of change of the drive voltage was 50% with reference to the drive voltage before photoirradiation.

In the organic EL device according to Inventive Example 4, the rate of change was further reduced over 15 hours from irradiation starting as compared with the organic EL device according to Inventive Example 5. After the lapse of the irradiation time of 15 hours, the rate of change of the drive voltage was 33% with reference to the drive voltage before photoirradiation.

In the organic EL device according to Inventive Example 3, the rate of change was further reduced over 15 hours from irradiation starting as compared with the organic EL device according to Inventive Example 4. After the lapse of the irradiation time of 15 hours, the rate of change of the drive voltage was 24% with reference to the drive voltage before photoirradiation.

In the organic EL device according to Inventive Example 2, the rate of change was further reduced over 15 hours from irradiation starting as compared with the organic EL device according to Inventive Example 3. After the lapse of the irradiation time of 15 hours, the rate of change of the drive voltage was 16% with reference to the drive voltage before photoirradiation.

In the organic EL device according to Inventive Example 1, the rate of change was further reduced over 15 hours from irradiation starting as compared with the organic EL device according to Inventive Example 2. After the lapse of the irradiation time of 15 hours, the rate of change of the drive voltage was 9% with reference to the drive voltage before photoirradiation.

Comparing the organic EL devices according to Inventive Examples 1 to 5 with that according to comparative example, it has been clarified that voltage increase deterioration of an organic EL device can be suppressed by providing a filter blocking transmission of light having a specific wavelength.

Comparing the organic EL devices according to Inventive Examples 1 to 3 with each other, the voltage increase deterioration was reduced as the transmittance was reduced (see FIG. 14) in the wavelength range from a wavelength shorter by 50 nm than the maximum electromotive wavelength of about 400 nm to a wavelength longer by 50 nm. Consequently, it has been clarified that an organic EL device can suppress voltage increase deterioration by blocking entrance of light having a wavelength generating electromotive force.

The organic EL devices according to Inventive Examples 4 and 5 are compared with each other. The filter F4 of the organic EL device according to Inventive Example 4 exhibited higher transmittance than the filter F5 of the organic EL device according to Inventive Example 5 in the wavelength range of 350 nm to about 420 nm, while the former exhibited lower transmittance than the latter in the wavelength range of about 420 nm to about 500 nm (see FIG. 14).

According to FIG. 1, the optical power generation characteristic (solid line K1) of the organic EL devices according to Inventive Examples 4 and 5 is softly inclined on the long-wavelength side with reference to the maximum electromotive wavelength of 400 nm, and slightly steeply inclined on the short-wavelength side. Thus, the organic EL devices according to Inventive Examples 4 and 5 were easily influenced by light on the long-wavelength side with reference to the maximum electromotive wavelength.

Therefore, the voltage increase deterioration in the organic EL device according to Inventive Example 4 was reduced as compared with that in the organic EL device according to Inventive Example 5 although the filter F4 of the former exhibited higher transmittance than the latter at the maximum electromotive wavelength, conceivably because of the optical power generation characteristic of the organic EL device.

FIG. 16 is a graph showing changes of luminance of the organic EL devices according to Inventive Examples and comparative example. Referring to FIG. 16, the axis of ordinate shows the rates of change (before photoirradiation: 100%) of the luminance, and the axis of abscissa shows times of continuous photoirradiation with the solar simulator.

Referring to FIG. 16, the solid line F1, the broken line F2, the one-dot chain line F3, the two-dot chain line F4, the dotted line F5 and the wide line FN show the changes of the luminance of the organic EL devices according to Inventive Examples 1 to 5 and comparative example respectively.

According to FIG. 16, the organic EL device according to comparative example provided with no filter exhibited slight reduction of the luminance over 15 hours from irradiation starting. After the lapse of the irradiation time of 15 hours, the rate of change of the luminance was 7% with reference to the luminance before photoirradiation.

In the organic EL device according to Inventive Example 5, on the other hand, the rate of change was reduced over 15 hours from irradiation starting as compared with the organic EL device according to comparative example. After the lapse of the irradiation time of 15 hours, the rate of change of the luminance was 5% with reference to the luminance before photoirradiation.

In the organic EL device according to Inventive Example 4, the rate of change was reduced over 15 hours from irradiation starting as compared with the organic EL device according to comparative example. After the lapse of the irradiation time of 15 hours, the rate of change of the luminance was 6% with reference to the luminance before photoirradiation.

In the organic EL device according to Inventive Example 3, the rate of change was reduced over 15 hours from irradiation starting as compared with the organic EL device according to comparative example. After the lapse of the irradiation time of 15 hours, the rate of change of the luminance was 2% with reference to the luminance before photoirradiation.

In the organic EL device according to Inventive Example 2, the rate of change was reduced over 15 hours from irradiation starting as compared with the organic EL device according to comparative example. After the lapse of the irradiation time of 15 hours, the rate of change of the luminance was 2% with reference to the luminance before photoirradiation.

In the organic EL device according to Inventive Example 1, the rate of change was reduced over 15 hours from irradiation starting as compared with the organic EL device according to comparative example. After the lapse of the irradiation time of 15 hours, the rate of change of the luminance was 3% with reference to the luminance before photoirradiation.

Comparing the organic EL devices according to Inventive Examples 1 to 5 with the organic EL device comparative example, it has been clarified that deterioration of the luminance of an organic EL device can be suppressed by providing a filter blocking transmission of light having a specific wavelength.

However, each rate of change of 2 to 7% upon continuous irradiation for 15 hours was extremely low, and there is conceivably no clear correlation between deterioration of luminance and optical power generation of an organic EL device.

Although the present invention has been described and illustrated in detail, it is clearly understood that the same is by way of illustration and example only and is not to be taken by way of limitation, the spirit and scope of the present invention being limited only by the terms of the appended claims.

1. An organic electroluminescent device comprising:
a light emitting layer composed of an organic compound; and
a light blocking layer blocking incidence of light in a prescribed wavelength range in said light emitting layer, wherein
said light emitting layer generates a voltage having a peak at a specific wavelength by external photoirradiation, and
said prescribed wavelength range includes said specific wavelength.

2. The organic electroluminescent device according to claim 1, wherein
said prescribed wavelength range includes a range from said specific wavelength to a wavelength longer by 50 nm than said specific wavelength.

3. The organic electroluminescent device according to claim 1, wherein
said prescribed wavelength range further includes a range from said specific wavelength to a wavelength shorter by 50 nm than said specific wavelength.

4. The organic electroluminescent device according to claim 1, wherein
said prescribed wavelength range further includes a range from said specific wavelength to a wavelength longer by 100 nm than said specific wavelength.

5. The organic electroluminescent device according to claim 1, wherein
said prescribed wavelength range further includes a range from said specific wavelength to a wavelength shorter by 100 nm than said specific wavelength.

6. The organic electroluminescent device according to claim 1, wherein
transmittance in said light blocking layer at said specific wavelength is lower than the maximum transmittance on the long-wavelengthlength side beyond said prescribed wavelength range.

7. The organic electroluminescent device according to claim 1, wherein
the maximum transmittance in said light blocking layer in said prescribed wavelength range is lower than the maximum transmittance on the long-wavelengthlength side beyond said prescribed wavelength range.

8. The organic electroluminescent device according to claim 1, wherein
transmittance in said light blocking layer at said specific wavelength is not more than 80%.

9. The organic electroluminescent device according to claim 1, wherein
the maximum transmittance in said light blocking layer in said prescribed wavelength range is not more than 80%.

10. The organic electroluminescent device according to claim 1, further comprising a light-transmitting electrode provided on one side of said light emitting layer, wherein
said light blocking layer is arranged on said one side of said light emitting layer.

11. The organic electroluminescent device according to claim 1, wherein
said light blocking layer includes an optical filer arranged on said one side of said light emitting layer.

12. The organic electroluminescent device according to claim 1, wherein
said light blocking layer includes a thin film arranged on said are side of said light emitting layer.

13. The organic electroluminescent device according to claim 1, wherein
said light-transmitting electrode includes said light blocking layer.

14. The organic electroluminescent device according to claim 1, further comprising an organic compound layer provided between said light emitting layer and said light-transmitting electrode, wherein
said organic compound layer includes said light blocking layer.

15. The organic electroluminescent device according to claim 1, further comprising a light-transmitting substrate, wherein
said substrate includes said light blocking layer.
